(19) United States
(12) Patent Application Publication
(10) Pub. No.: US 2015/0291830 A1
(43) Pub. Date: Oct. 15, 2015

(54) APPARATUS AND METHODS FOR PLASMA ENHANCED CHEMICAL VAPOR DEPOSITION OF POLYMER COATINGS

(71) Applicant: LIQUIPEL IP LLC, Santa Ana, CA (US)

(72) Inventors: Herbert Vincent Galbreath, Portola Hills, CA (US); Alexander Hill, South Coast Metro, CA (US); Daniel Storey, Longmont, CO (US)

(21) Appl. No.: 14/442,944

(22) PCT Filed: Nov. 14, 2013
(86) PCT No.: PCT/US2013/070017

§ 371 Date: May 14, 2015

Related U.S. Application Data
(63) Continuation-in-part of application No. 13/838,612, filed on Mar. 15, 2013.
(60) Provisional application No. 61/727,396, filed on Nov. 16, 2012.
(60) Provisional application No. 61/727,873, filed on Nov. 19, 2012.
(60) Provisional application No. 61/727,891, filed on Nov. 19, 2012.

(51) Int. Cl. C09D 133/16; C23C 16/505; H05K 3/28; H01L 21/02; H01L 21/56; C23C 16/50; D06M 15/256

(52) U.S. Cl. CPC C09D 133/16; C23C 16/50; C23C 16/505; D06M 15/256; H01L 21/02118; H01L 21/02274; H01L 21/56; H05K 3/28; D06M 2200/12; H05K 2201/0179

(57) ABSTRACT

Apparatuses and methods are described that involve the deposition of polymer coatings on substrates. The polymer coatings generally comprise an electrically insulating layer and/or a hydrophobic layer. The hydrophobic layer can comprise fused polymer particles have an average primary particle diameter on the nanometer to micrometer scale. The polymer coatings are deposited on substrates using specifically adapted plasma enhanced chemical vapor deposition approaches. The substrates can include computing devices and fabrics.

### CROSS REFERENCE TO RELATED APPLICATIONS

This application claims priority to U.S. provisional application No. 61/727,873, filed Nov. 19, 2012, and is a continuation-in-part of U.S. patent application Ser. No. 13/838,612, filed Mar. 15, 2013; which claims priority to U.S. provisional application No. 61/727,891, filed Nov. 19, 2012 and entitled “Polytetrafluoroethylene-Like/Plasma Enhanced Polymer Nano Spheroid Deposition Co-Deposition for Surface Property Improvement” and U.S. provisional application No. 61/727,396, filed Nov. 16, 2012 and entitled “Plasma Enhanced Polymer Nano Spheroid Deposition for Surface Property Improvement;” all of which are hereby incorporated herein by reference.

### BACKGROUND

Many coatings are known for adding water or wear resistance to a bulk material. These range from familiarly known paints or waxes to high-technology chemical formulations. Plasma enhanced chemical vapor deposition is a coating technique that has been used to make coatings on surfaces, such as for semiconductor or high performance optical glasses. Conventional wisdom teaches that it is not possible to provide a surface modification on that comprises an open, spheroid structure throughout its structure with certain types of plasma polymerization processes.

### SUMMARY OF THE INVENTION

In a first aspect, the invention pertains to a method for forming a protective coating on a substrate. The method comprises depositing a collection of polymer particles having an average primary particle diameter of from about 20 nm to about 10 microns on the substrate to form a fused nanoparticle layer.

In a second aspect, the invention pertains to a structure comprising coating disposed on substrate, wherein the coating comprises a first polymer layer disposed on the substrate and a second polymer layer disposed on the first polymer layer, wherein the second polymer layer comprises fused polymer particles having an average primary particle size of from about 200 nm to about 100 microns.

### BRIEF DESCRIPTION OF THE DRAWINGS

FIG. 1 is a drawing of schematic representation of a PECVD apparatus.

FIG. 2 is a drawing of a schematic representation of a precursor delivery system.

FIG. 3 is an scanning electron microscopy (SEM) image of the surface of a hydrophobic layer deposited on a silicon chip.

FIG. 4 is an SEM image of the surface depicted in FIG. 3, taken at higher resolution.

FIG. 5 is an SEM image of the surface of a hydrophobic layer deposited on a silicon chip, the hydrophobic layer formed from a different precursor composition than was used to form the hydrophobic layer depicted in FIGS. 3 and 4.

FIG. 6 is a photographic image of a water droplet on the coating of sample 2 taken during goiniometric analysis.

FIG. 7 is a photographic image of a water droplet on the coating of sample 3 taken during goiniometric analysis.

FIG. 8 is a photographic image of a water droplet on the coating of sample 4 taken during goiniometric analysis.

FIG. 9 is a photographic image of the interior portion of an as-purchased mobile phone taken after a being submerged in water.

FIG. 10 is a photographic image of the interior portion of a mobile phone having a deposited polymer taken after being submerged in water.

FIG. 11 is a photographic image of a water droplet on the coating of sample 5 taken during goiniometric analysis.

FIG. 12 is a photographic image of a water droplet on the coating of sample 6 taken during goiniometric analysis.

FIG. 13 is a photographic image of a water droplet on the coating of sample 7 taken during goiniometric analysis.

FIG. 14 is a drawing of a schematic representation of an electrolysis test configuration.

FIG. 15 is a graph showing plots of current versus time generated by electrolysis tests conducted on an as-purchased circuit board and a circuit board having a deposited polymer coating.

FIG. 16 is an SEM image of an electrically isolating layer deposited on circuit board.

FIG. 17 is a photographic image of a water droplet on the coating of sample 8 taken during goiniometric analysis.

FIG. 18 is a photographic image of a water droplet on the coating of sample 9 taken during goiniometric analysis.

FIG. 19 is a photographic image of a water droplet on the surface of an as-purchased circuit board taken during goiniometric analysis.

### DETAILED DESCRIPTION

Described herein are apparatuses and methods for plasma enhanced chemical vapor deposition (“PECVD”) of polymer coatings. The polymer coatings can surface modify the surfaces of substrates such that the substrates can substantially retain their inherent properties. In some embodiments, the polymer coatings can comprise a plurality of layers that provide for different types of protection to the underlying substrate. In some embodiments, the coatings can comprise an electrically insulating layer and a hydrophobic polymer layer. The layers can be desirably formed from polymerizable species using adapted PECVD processes described herein.

The coatings described herein can be deposited on a wide variety of substrates including, but not limited to substrates comprising glass, optical materials, fiber glass, building materials, natural materials (like leather), polymers and ceramics. The substrate may or may not have functionality beyond the bulk properties of the materials. In some embodiments, the coatings described herein are desirably benign to the functional properties of a substrate such that the functionality of the substrate is preserved after deposition of the polymer coating. For example, in some embodiments, the substrate can comprise functional devices such as an electronic components, including but not limited to circuit boards and the like, as well as computing devices, including but not limited to laptop computers, tablet computers, mobile phones, portable music players and the like. Moreover, the polymer coatings can have high level of transparency and, therefore, can provide protection to a substrate in application settings where it is desirable to see the substrate through the polymer layer. For example, such application settings can involve the deposition of coatings on devices incorporating a display, including but not limited to computing devices (including mobile computing devices such as tablets and mobile phones), televisions, polymer and/or glass windows or coatings and the like. In some embodiments, polymer coatings can be applied to fabrics such as articles of clothing and the like, including but not limited to, shirts and shoes. In general, the adapted processing approaches described herein are desirably mild such that a polymer coating can be applied to a variety of substrates without damaging the substrate.

The coatings may be formed from monomers that provide a surface with a desired degree of surface energy, such as being hydrophilic, hydrophobic, highly hydrophobic, or super-hydrophobic. A surface is considered hydrophilic when the water contact angle is smaller than 90°. The solid surface is considered hydrophobic when the water contact angle is from 90° to about 115°. A highly hydrophobic surface has a water contact angles of more than about 115° to about 150°. A super-hydrophobic surface has a water contact of more than 150°. Contact angles are preferably measured as dynamic contact angles.

An insulating layer can comprise a polymer layer that helps to prevent conduction from the underlying substrate though the insulating layer. Improved PECVD processing approaches can provide for improved polymer layers which can also be, to a relatively large extent, free from pin-hole structures through the insulating layer, relative to PECVD techniques known in the art. Pin-hole structures comprise holes through the layer that can allow for passage of liquid through the layer to the underlying substrate such that layers having reduced pin-hole structures provide for improved hydrophobicity. However, in some embodiments, the reduced amount of pin-hole structures may not provide a desirable level of hydrophobicity and, therefore, in some embodiments it can be desirable for the coating to comprise an additional layer to provide improved hydrophobicity of the coating as a whole.

A hydrophobic layer can comprise a particulate particle layer that can help to prevent the passage of liquid the layer. The hydrophobicity of a coating can be measured by measuring the equilibrium contact angle of the liquid/vapor interface at the solid boundary between the coating and a drop of liquid deposited thereon. The contact angle is generally measured relative to an axis along planar surface of the coating and directed towards the center of the droplet with an origin at the point of contact between the liquid drop and the coating. Contact angles can be measured optically by taking an optical image of a water droplet on a surface and measuring the contact angle between the water droplet and the surface. Optical contact angle analysis can be performed using commercially available goniometers such as the VCA Optima S goniometer (AST Products, Inc., Billerica, Mass.). Hydrophobic surfaces generally have a contact angle of from about 90° to about 180°, with larger contact angles reflecting more hydrophobic surfaces. In some embodiments, the hydrophobic layer can have a contact angle with water that from about 90° to about 160° and, in further embodiments, form about 110° to about 150° and, in further embodiments from about 130° to about 145°. A person of ordinary skill in the art will recognize additional ranges within the explicitly recited ranges are contemplated and within the present disclosure.

The hydrophobic layer can comprise a porous layer having polymer particles fused to the underlying substrate and/or a porous network of fused particles that is also fused to the substrate. The polymer particles can have a generally spheroidal shape. While there are various mechanisms that can provide for varying degrees of polymer particle-particle fusing, without being limited by a theory, such mechanisms can include, but are not limited to, interdigitation of polymer chains between adjacent particles and/or cross-linking of polymers between adjacent particles. The polymer particles can have a range of average primary particle size from the nanometer scale to the micrometer scale. Primary particles diameter refers to the diameter of the unfused particles. The primary particle size can be determined form scanning electron microscopy (“SEM”) images taken of the deposited particulate layers. Although the deposited particles comprise particles that are fused to the underlying structure and/or to each other, the primary particle structure can still be estimated from the SEM images. The diameter of a particle is taken as the longest linear dimension of the deposited particle. In some embodiments, the polymer particles can have an average primary particle diameter of no more than about 10 μm; in further embodiments, no more than about 1 μm; in further embodiments, no more than about 200 nm; and in further embodiments from about 5 nm to about 20 nm. A person of ordinary skill in the art will recognize additional ranges within the explicitly recited ranges are contemplated and within the present disclosure.

In some embodiments, the coating can comprise either an insulating layer or a hydrophobic layer. The desirability of each coating can depend upon the particular application and, therefore, in some embodiments a coating comprising a single layer can be desirable. For example, in application settings where reasonable electrical insulation may be desired but not a relatively high level of hydrophobic protection, the coating can comprise only the electrically insulating layer. For other applications, such as for textile coatings, electrical insulation may not be desired and the hydrophobic layer alone may provide desirable protection.

Coatings may be formed of a single layer, or a plurality of layers. A layer in a coating has contact with another layer in the coating, with the contact being complete or partial. A coating can have variable characteristics. Thus a coating may be discontinuous with a surface at some points and still retain its characteristic as a coating. In general, however, coatings that are free of defects may be made using the plasma-based processes described herein, so that the coatings, or a layer of a coating, may be continuous and/or be free of pinholes and/or free of electrically-detectable gaps. Coatings, and layers, can have a selected thickness, selected composition, variable chemical properties based on the teachings herein. Coatings, and layers, may cover all or a portion of a surface. Layers may, e.g., be superimposed upon other layers to create a coating. The first layer and second layers may be applied in any order, e.g., starting with the first, then the second, or vice versa. Additional layers may be similarly formed and used. Layers may be made from a single type of monomer or a plurality of monomers. Some layers are useful for providing a base layer that contacts a device and serves to anchor subsequently applied layers.

As described in detail below, the layers are polymeric layers. The polymers comprise many repeat subunits formed from monomers that are polymerized. The polymers in the polymeric layer can comprise at least 2, at least 100, at least 1000, at least 10000, at least 100,000 or more repeat subunits. The polymers may be cross-linked or not cross-linked, depending on the particular reaction and monomeric precursors that are used. The term monomer refers to a molecule group that can combine with others of the same kind to form a polymer. Vinylic and epoxide monomer groups are generally useful in plasma-based polymerization processes. The term vinylic refers to the functional group C═C. The term epoxide refers to a 3-membered cyclic ether. The term group indicates that the generically recited chemical entity (e.g., alkyl group) may have any substituent thereon which is consistent with the bond structure of that group. For example, where the term ‘alkyl group’ is used, that term would not only include unsubstituted linear, branched and cyclic alkyls, such as methyl, ethyl, isopropyl, tert-butyl, cyclohexyl, dodecyl and the like, but also substituents having heteroatom such as 3-ethoxylpropyl, 4-(N-ethylamino)butyl, 3-hydroxypentyl, 2-thiolhexyl, 1,2,3-tribromopropyl, and the like. However, as is consistent with such nomenclature, no substitution would be included within the term that would alter the fundamental bond structure of the underlying group.

The average thickness of the coatings can be selected based upon the desired level of electrical conductivity and/or hydrophobicity, which a person of ordinary skill with be able to determine based upon the application setting. In some embodiments, a coating can comprising an electrically insulating coating having an average thickness of from about 1 nm to about 1 micron; in further embodiments, about 1 nm to about 500 nm and, in further embodiments, from about 100 nm to about 200 nm. In some embodiments comprising a hydrophobic coating, the hydrophobic coating can have an average thickness from about 1 nm to about 1 micron; in further embodiments, from about 1 nm to about 500 nm and, in further embodiments, from about 200 nm to about 300 nm. A person of ordinary skill in the art will recognize additional ranges within the explicitly recited ranged are contemplated and within the present disclosure.

The coatings described herein can be desirably formed using specifically adapted PECVD processes. PECVD processes involve the plasma driven polymerization of monomers from a precursor composition. In some embodiments, an adapted PECVD process can desirably incorporate a capacitatively coupled plasma (“CCP”). Relative to inductively coupled plasmas (“ICP”), where the plasma is produced by electromagnetic induction, CCPs can be less dense and can result in more limited dissociation of monomers within the precursor. In general, a plasma is formed by applying an electric field/electromagnetic field to vapor phase precursor composition comprising one or more monomer species that are susceptible to radical polymerization. Without being limited by a theory, it is believed the field can activate monomer species so that they are absorbed onto the surface of the substrate in contact with the plasma and bonded together to polymerize. The characteristics of the field can significantly affect the composition, structure and/or properties of the deposited polymer layers. The field can comprise a DC field, i.e., a continuous field, or AC field, such as a periodic field, e.g., an RF field. As used herein, a continuous field refers to a field that is generated when power is continuously supplied to the electrodes as either a DC current or a periodic current. A pulsed field refers to a DC field or an AC field that is switched on and off by toggling the power to the electrodes, which may or may not be periodic, and which may be specified by a duty cycle as described below. The pulsing of an AC field generally refers to a gating of the periodic field at a lower frequency than the frequency of the AC field itself. The power of the resulting power generated by the field can be at least partially determined by the amplitude of the voltage applied to create the field. Additionally, it is noted that herein, as well as in the art, pulsed and continuous fields are used synonymously with pulsed and continuous plasmas.

It has surprisingly been discovered that PECVD processing approaches incorporating continuous fields and high power densities can form electrically insulating layers having improved resistivity and hydrophobicity. Additionally, it has been surprisingly found that PECVD processing approaches incorporating continuous or pulsed fields in conjunction with pulsed precursor compositions can form polymer particles which are deposited and fused onto a substrate in contact with the plasma to form a particulate polymer layer having improved hydrophobicity relative to polymer hydrophobic layers not are not particulate.

In some embodiments, depositing an insulating layer and/or a hydrophobic layer can comprises depositing a layer covering essentially an entire substrate or a surface thereof. In some embodiments, depositing an insulating layer and/or a hydrophobic layer can comprises depositing the layer on only a portion of a substrate. In some embodiments, a mask can be used to deposit a layer at one or more selected locations on a substrate. Masks are known in the art can be adapted for the processing purposes described herein. In some embodiments, the mask can be chemically or physically bonded to the surface with atomic level contact along the mask. In some application settings, a mask that is chemically or physically bonded to the substrate may not be desirable because removing the mask can involve etching with potentially corrosive compositions (relative to the composition of the substrate and/or coatings) and/or further substrate cleaning due to residue left behind after the mask is removed. Mask that chemically or physically bond to the surface of the substrate can be formed and/or applied using methods well known in the art including, but not limited to, photoresist techniques and taping techniques.

In other embodiments, the mask can comprise a flat surface(s) that is(are) placed against the surface(s) of the substrate to cover a selected portion of a substrate such that the coating is substantially blocked from reaching covered portions of the substrate. The surface-to-surface contact can provide sufficient contact to prevent significant migration of layer deposition material past the mask. Such masks can be desirable in some application because their removal general requires the application of physical force to separate the mask from the substrate. Mask that do not chemically or physical bond to the surface of the substrate can be formed and/or applied using methods well known in the art including, but not limited to, stenciling techniques.

### PECVD Apparatus

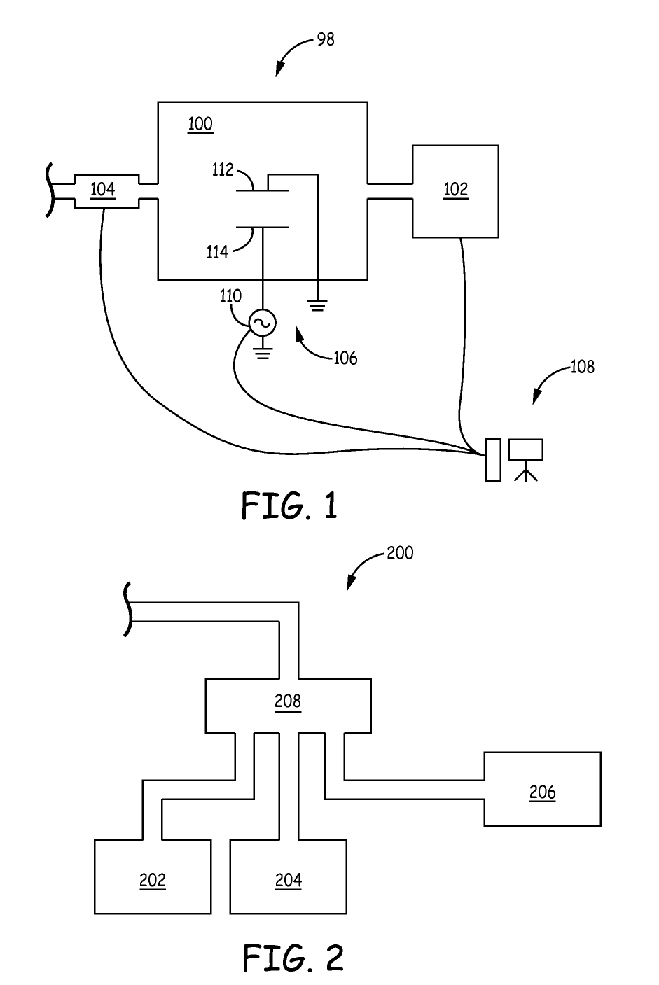

FIG. 1 is a schematic representation of a PECVD apparatus that can be used to form the coatings described herein. Referring to the figures, the PECVD apparatus comprises vacuum chamber 100, precursor deliver system 102, evacuation system 104, field generation system 106, and computer control system 108. Vacuum chamber 100 can have can any reasonable shape, including, but not limited to a cuboid or a cylindrical shape and can be formed from any suitable material, including but not limited to aluminum, stainless steel and carbon steel. The volume of the vacuum chamber can be selected based on a variety of factors including, but not limited do, the desired processing conditions, the size of the substrate or substrates (if simultaneous coating of a plurality of substrates is desired), and field power and the desired amount of precursor material to be used for a given deposition. In some embodiments, a vacuum chamber can have a volume of no more than about 1000 L and, in other embodiments, from about 5 L to about 1000 L. In some embodiments of a PECVD apparatus, heater can be coupled to vacuum chamber 100 to help maintain a constant temperature within vacuum chamber 100. The heater can be coupled to the interior or exterior of the vacuum chamber. In some embodiments, the heater can be a rope heater.

Precursor delivery system 102 can provide for delivery of precursor compositions into vacuum chamber 100. Precursor deliver system 102 can be configured to deliver precursor compositions comprising monomers and, optionally, other carrier and/or activation gasses into vacuum chamber 100 at desired relative concentrations and flow rates. Carrier gases can include, for example, argon, nitrogen, and oxygen. Activator gasses can facilitate the polymerization process and can include, for example, ozone. In some embodiments, A PECVD apparatus can be configured with multiple precursor delivery systems such that each system delivers one or more precursor monomers and/or carrier gasses. FIG. 2 shows an embodiment of a precursor delivery system. Referring to the figure, precursor delivery system 200 comprises monomer sources 202, 204, carrier gas source 206 and mixing system 208. Precursor composition sources 202, 204 can comprise different precursor material provided in vapor or gas form to mixing system 208. In some embodiments, the precursor material can be supplied to vacuum chamber in a liquid, solution, aerosol of a liquid, liquid solution, liquid mixture and/or dispersed solid particle (that can sublime in the vacuum chamber). Mixing system 208 comprises a manifold with independent flow control of each monomer source 202, 204 and carrier gas source 206 and can provide for desired relative concentrations of monomers, carrier gasses and to vacuum chamber 100. Evacuation system 104 can provide for evacuation of vapor/gas materials form the interior of vacuum chamber 100 and comprise a pump or the like.

The field generation system 106 provides the excitation for plasma generation from the precursor compositions. Field generation system 106 comprises power supply 110 and electrodes 112, 114. Power supply 110 can comprises a power supply capable of producing a field across electrodes 112, 114. Power supply 110 can be configured to produce fields having characteristics described below.

In some embodiments, it can be desirable to place the substrate between electrodes 112, 114. In some embodiments, electrode 112 or 114 can comprise a substrate support. In some such embodiments, the substrate support can be coupled to a heating element to heat the substrate to aid deposition thereon.

Computer control system 108 can comprise a computing device to provide for automation of the processes described herein. Computer control system 108 is communicatively coupled to evacuation system 102 and 104 to independently control the flow of monomers and/or carrier gasses and/or activation gasses into and/or out of vacuum chamber 100. For example, in precursor delivery system 200, computer control system 108 can be communicatively coupled to mixing system 208 to independently control the flow for each monomer and carrier gas as well as the relative concentrations thereof. Computer control system 108 is also communicatively coupled to power supply 110 to control the flow and type of power delivered to electrodes, as well as the characteristics of the field thereby generated, as described above. In some embodiments, Computer control system 108 can comprise a computing device having a processor and accessible memory, such as a desktop computer or mobile computing device including, but not limited to, a laptop computer, a tablet computer, or mobile phone. The accessible memory of the computing device can comprise instructions that, when executed by the processor, allow for control of various components of the PECVD apparatus to automate the processes described herein.

As explained above, in some embodiments, the processes described herein can comprise a cleaning process and one or more deposition processes. In some embodiments, computer control system 108 can be configured to automate each of the process so that a user can place a substrate into PECVD apparatus 98 and, thereafter, the computer can configure the PECVD to perform the cleaning process and/or one or more of the deposition processes without human intervention.

### Processing

To form the improved coatings herein, adapted PECVD processes can employed. Prior to deposition of a polymer layer, optionally, coating substrate can be cleaned to remove contaminants thereon. Subsequently, in some embodiments, an electrically insulating layer can be deposited on the substrate and a hydrophobic layer can be deposited on the electrically insulating layer. As described above, in some embodiments, the coatings of interest herein can comprise an electrically insulating layer without a hydrophobic layer or a hydrophobic layer without an electrically insulating layer. Although the PECVD processing is described herein in relation to a coating comprising an electrically insulating layer and a hydrophobic layer, a person of ordinary skill in the art will recognized that the individual description relating to the deposition of either layer can be used to form the corresponding layer without the formation of the other.

Prior to deposition of any polymer layer, the substrate can be cleaned using a variety of approaches known in the art. In some embodiments, the substrate can be cleaned using appropriate solvents such as alcohols or dilute acids and/or ultrasonic cleaning with subsequent drying of the substrate in an oven (e.g., a kiln). In additional or alternative embodiments, substrate can be cleaned using a plasma. For plasma cleaning, plasma activated species formed from oxygen and/or ozone can be particularly effective in removing organic contaminants from the surfaces of the substrate. For substrates comprising readily oxidizable material such as silver or copper, more inert precursors such as argon, nitrogen and/or helium can be used in a plasma cleaning process. Plasma cleaning of the substrate can be desirable because a PECVD apparatus configured to incorporate the processing approaches described herein can similarly be configured to perform plasma cleaning of the substrate in an automated process. For example, referring to FIG. 1, precursor delivery system 102 can be configured to deliver oxygen, ozone, argon, nitrogen, and/or helium (as well as other monomers for deposition of the polymer coating) into vacuum chamber 100 and computer control system 108 can be configured to adjust the parameters of field generation system 106. In operation, computer control system 106 would first configure precursor deliver system to deliver one or more of the aforementioned compounds into vacuum chamber 100 and configure field generation system 106 to provide the desired field (e.g., a continuous, RF field). After a desired time, computer control system 108 could reconfigure PECVD apparatus 98 to deposit the polymer coating as described below. In some embodiments, subsequent to cleaning and prior to deposition of the polymer coating, an outgassing process can be performed. Outgassing can involve evacuating the vacuum chamber to an outgassing pressure to and maintaining the outgassing pressure for a desired amount of time. In some embodiments, the cleaning and/or outgassing can be performed at a temperature of between 20° C. to 200° C. A person of ordinary skill in the art will recognized additional cleaning and/or outgassing temperatures within the explicitly disclosed ranges are contemplated and within the scope of the present disclosure.

Following optional cleaning of the substrate, the polymer coating can be deposited on the substrate using adapted PECVD processing approaches. In some embodiments, the plasma driven polymer vapor deposition can be useful for monomers that are susceptible to radical polymerization since the plasma can activate the compounds to induce polymerization. In particular, the monomers are introduced as a gas into the plasma, which results in energetic species, such as electrons, ions or photons, in the gas phase, consequently effecting the breaking of chemical bonds and thus creating free radicals that then are absorbed by the surface of the substrate and/or bond together and/or polymerize. For example, vinyl and polyether polymers can be synthesized through radical or ionic mechanisms, and correspondingly, vinyl and epoxide monomers, respectively, can be suitable precursors for the PECVD polymer deposition method. Vinyl compounds can be represented by the formula R₁R₂C═CR₃R₄, where each R individually can be hydrogen, halogen, an organic group, such as a hydrocarbon group or substituted hydrocarbon group. Epoxide compounds can be represented by the formula:

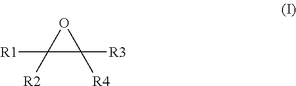

where each R individual can be as previously described. Without being limited by a theory, while both vinyl and epoxide monomers can be used in the PECVD processes described herein, it is believed that they polymerize through different mechanisms. In particular, it is believed that vinyl monomers can polymerize breaking the C═C double bond structure to from a radical C—C single bond structure. Epoxide monomers, it is believed, polymerize through ring opening accomplished by breaking the O—C bond to form a O—C—C radical structure.

The organic groups can comprise linear or branched (saturated or unsaturated) hydrocarbon chains generally with 1 to 20 carbon atoms, and in some embodiments 1-8 carbon atoms, and if further embodiments 2-6 carbon atoms. Fluorine substituted moieties can be desirable due to the resulting hydrophobic nature of fluorinated polymers, especially perfluorinated, i.e., compositions in which hydrogens are globally substituted with fluorine. In some embodiments, for epoxide monomers, R₁-R₃ can be hydrogen and R4 can be represented by the formula —CH₂(CF₂)ₙCF₃, where n is 1 to 20. In such embodiments, desireable epoxide monomers include, but are not limited to, 3-(perfluorooctyl)propyl epoxide and 3-(perfluorohexyl)propyl epoxide

Thus, for example, alkenes, such as fluorinated alkenes are suitable precursors. For vinyl monomers, acrylate based compositions can be used as precursors, which have a general composition of in which R₁ above is —COOR₅, where R₅ can be hydrogen (acrylic acid), or a hydrocarbyl group having between 1 and 20 carbon atoms. Specific embodiments of acrylate monomers include, for example, methacrylates (R₅═—CH₃), methyl acrylates (R₂═—CH₃), methyl metacrylates (R₂═—CH₃ and R₅═—CH₃), ethyl acrylates (R₅— —CH₂CH₃), buytl methacrylates (R₂═—(CH₂)₃CH₃ and R₅═—CH₃), partially fluorinated versions thereof, perfluorinated versions thereof and the like. In some embodiments, suitable vinyl precursors can include, but are not limited to, 1H,1H,2H,2H-tridecafluorooxtyl methacrylate and 1H,1H,2H,2H-perfluorodecyl acrylate. In some embodiment, suitable epoxide precursors can include, but are not limited to, compositions in which at least one of R1, R2, R3, or R4 is represented by the formula —CH₂(CF₂)ₘCF₃, where m is between 1 and 20, and the other R groups are a hydrogen.

As previously mentioned, specific PECVD processing approaches incorporating adapted process parameters are described herein for the deposition of the polymer coating. The field applied to the precursor compositions to generate the plasma can be a DC field or an AC field, e.g., a RF field. The DC field or AC field can also be continuous or pulsed, and the pulsing can be described in terms of a duty cycle, as explained below. In some embodiments, an AC field (including an RF field) can have a frequency of between about 10 Hz to about 3 Ghz; in further embodiments and, in further embodiments, from about 1 MHz to about 100 MHz. Commercial available AC (including RF) power generators generally operate at standard frequencies including, but not limited to, from about 50 Hz to about 60 Hz, 2 MHz, 13.56 MHz, and 40.68 MHz, and can be suitable power sources for the apparatuses and processes described herein. A person of ordinary skill in the art will recognize additional ranges of frequency within the explicitly disclosed ranges are contemplated and within the scope of disclosure. In some embodiments, in can be desirable to use a high frequency (i.e., greater than about 1 kHz) oscillating field. High frequency fields can be desirable because they allow for PECVD deposition onto non-conductive substrates. Additionally, factors such as deposition time, field operation mode (i.e., continuous or pulsed), plasma power density, precursor flow rate, working pressure, and temperature can all also affect the structure, composition and/or properties of the polymer coating. With respect to deposition time, a person of ordinary skill in the art will know how to select an appropriate deposition time to obtain a desired electrically insulating layer and hydrophobic layer thickness. Desirable field operation mode parameters, plasma power density parameters, pressures and temperatures are discussed below in relation to deposition of the individual electrically insulating and hydrophobic layers.

For PECVD of the electrically insulating layer, it has been surprisingly discovered that improved insulating layers can be formed from plasmas having relatively high power densities. Generally, higher power densities are associated with continuous fields and, therefore, in some embodiments, PECVD of the electrically insulating layer can comprise using a continuous field to generate a plasma having a relatively high power density. Most PECVD processes use pulsed plasmas to create relatively low power density plasmas to preserve the integrity of the monomer precursor until it polymerizes. Surprisingly, however, it has been discovered that by degrading the monomer precursor using a relatively high power density prior to polymerization, an electrically insulating layer having reduced pin-hole structures can be obtained, translating into improved electrical insulation and hydrophobicity.

As used herein, power density refers to the average power of the plasma divided by the volume of the vacuum chamber. The average power of the plasma can be defined as <P>=<Pₒₙ>*D, where <Pₒₙ> is the average power input power supplied to the electrodes and D is the duty cycle. For continuous wave plasmas, D=1 and <Pₒₙ>=<P_{CW}>, where <P_{CW}> is the average power of the continuous wave plasma. In some embodiments, for PECVD of the insulating layer, the plasma can have a power density of at least 0.2 watts per liter (“W/L”), or at least 3 W/L, or from about 0.5 W/L to about 10 W/L, or from about 1 W/L to about 5 W/L. A person of ordinary skill in the art will recognize that additional ranges of power densities within the explicit ranges above are contemplated and are within the present disclosure.

For PECVD of the insulating layer, in some embodiments, it can be desirable to perform the deposition at constant temperature and/or pressure. Performing PECVD at constant temperature and pressure can be desirable with respect to uniformity of deposited layer and the repeatability of the results. In some embodiments, constant pressure can be achieved by monitoring the pressure inside the vacuum chamber and adjusting the flow the precursor composition into the vacuum chamber to help maintain a desired pressure. In some embodiments, PECVD of the insulating layer can be performed using a pressure of about 100 millitorr (“mTorr”) to about 800 mTorr; in further embodiments, from about 200 mTorr to about 600 mTorr; and, in further embodiments, from about 350 mTorr to about 450 mTorr. In some embodiments, PECVD of the insulating layer can be performed at a constant temperature of from about 15° C. to about 200° C.; in further embodiments, from about 20° C. to about 150° C.; and in further embodiments; from about 30° C. to about 100° C. A person of ordinary skill in the art will recognize additional ranges of pressure and temperature within the explicitly disclosed ranges are contemplated and within the present disclosure.

With respect to the hydrophobic layer, the layer can be deposited on the substrate or an electrically insulating layer if an electrically insulating layer is first deposited on the substrate. Suitable monomer precursors for the PECVD of the polymer particle layer comprise the monomer precursors described above with respect to deposition of the electrically insulating layer. In embodiments comprising PECVD of a polymer coating can comprise deposition of an insulating layer and a hydrophobic layer, both formed from the same monomer precursor or both formed from different precursors.

For PECVD of the hydrophobic layer, it has been surprisingly discovered that by generating a plasma having a relatively low power density and by pulsing the precursor composition into the vacuum chamber of a PECVD apparatus, polymer particles can be deposited and fused to each other and/or the electrically insulating layer or substrate. In some embodiments, the low power density plasma can be a continuous wave plasma. In some embodiments, the low power density plasma can be a pulsed plasma. The PECVD approaches used herein incorporating low power density plasmas and pulsed precursor compositions can allow for a more uniform, more consistent and more controllable hydrophobic layer deposition. Without being limited by a theory, it is believed that the aforementioned improvements result from an adiabatic expansion period for the precursor composition during precursor pulsing, as explained in detail below.

For PECVD of hydrophobic layers, the continuous or pulsed plasma can have an average power density of between 0.001 W/L to about 10 W/L; in other embodiments, from about 0.001 W/L to about 1 W/L; and in further embodiments, from about 0.001 W/L to about 1 W/L. A person of ordinary skill in the art will recognize additional ranges of power density within the explicitly disclosed ranges are contemplated and within the scope of disclosure. In general, plasmas having relatively low power densities are associated with pulsed fields and, therefore, in some embodiments, PECVD of a hydrophobic layer can comprise deposition using a pulsed field. In some embodiments, the gating of the field, i.e., the period of field bursts, can be described in terms of a frequency from about 5 kHz to about 250 kHz; in other embodiments, from about 10 kHz to about 150 kHz; and in further embodiment, from about 25 kHz to about 105 kHz. In some embodiments, the field can be pulsed with a duty cycle of about 0.5% to about 5%; in other embodiments from about 1% to about 4%; and, in further embodiments, from about 2% to about 3%. The duty cycle can be defined as the ratio of the pulse duration to the period. For example, if an RF field is pulsed with a period of 100 seconds using a duty cycle of 2%, an RF field is generated for 2 second followed by a 98 second interval where the RF field is turned off, prior to a subsequent 2 second RF field pulse. A person of ordinary skill in the art will recognize additionally ranges of frequencies and duty cycles within the explicitly claimed ranges are contemplated and within the present disclosure.

With respect to precursor pulsing, the process can involve discretely pulsing the precursor composition into the reaction chamber to allow for deposition of the hydrophobic layer in a sequence of discrete PECVD processes. A precursor pulse cycle can comprise a pressurization phase, a soak phase (adiabatic expansion phase) and an evacuation phase. The number pulse cycles can be selected based on the desired thickness of the deposited hydrophobic layer, where a larger number of cycles can correspond to a thicker hydrophobic layer and a smaller number of cycles can correspond to a thinner hydrophobic layer. In some embodiments, the number of pulse cycles can be between 2 and 10,000; in further embodiments, between 2 and 1000; in further embodiments, between 2 and 100; in further embodiments, between 2 and 75; and, in further embodiments, between 2 and 50. A person of ordinary skill in the art will recognize additional ranges within the explicitly disclosed ranges are contemplated and within the present disclosure.

The pressurization phase can comprise pressurizing the vacuum chamber to a target pressure. In some embodiments, the pressurizing phase can also operate as a purging mechanism. In some such embodiments, the flow of precursor composition through the vacuum chamber can be maintained at the target pressure (or a different pressure) for a given time period to help purge the vacuum chamber with the precursor composition. In general, the target pressure can be selected based on the processing conditions desired for the subsequent soak phase. In some embodiments, the target pressure can be from about 0.02 mTorr to about 500 mTorr; in further embodiments, from about 0.01 mTorr to about 200 mTorr; in further embodiments, from about 0.1 mTorr to about 100 mTorr. A person of ordinary skill in the art will recognize that additional ranges within the explicit ranges above are contemplated and are within the present disclosures.

The soak phase (adiabatic expansion phase) can comprise isolating the vacuum chamber from flow into and out of the chamber. The soak phase can provide for PECVD at constant volume. In some embodiments, while the reactant components (i.e., monomers) of the precursor composition are prevented from flowing into the chamber, the carrier gas component is allowed to flow into the chamber during the soak period to help maintain a target pressure. Without being limited by a theory, it is believed that along with processing parameters comprising relatively low power density plasmas and pulsed precursor compositions, the soak phase can be desirable to help quench polymer particle growth such that deposited layer comprise a particulate polymer layer. The duration of the soak phase can be selected relative to the initial pressure at the beginning of the soak phase. In some embodiments, the duration of the soak phase can affect particle size, with longer soak times corresponding to the production polymer layers having polymer particles with larger average primary particles sizes and shorter soak times corresponding to the production of polymer layers having polymer particles with smaller average primary particle sizes. In particular, the combination of selected initial pressure at the outset of the soak phase process and selected soak phase duration, in combination with other parameters, can affect polymer particle size. In some embodiments, the soak time can be between about 0.1 seconds to about 10 minutes; in further embodiments, from about 0.1 seconds to about 10 minutes; in further embodiments, from about 1 second to about 5 minutes; in further embodiments, from about 1 second to about 2 minutes and in further embodiments; from about 1 seconds to about 30 seconds. A person of ordinary skill in the art will recognize additionally ranges of soak period durations within the explicitly disclosed ranges are contemplated and within the scope of the disclosure.

The evacuation phase comprises evacuating the vacuum chamber to remove a portion of the plasma material prior to the next pressurization phase. While not being limited by a theory, it is believed that evacuation can help quench the particle formation process by lowering the monomer concentration in the vacuum chamber and, in combination with the pressurization phase parameters and soak phase parameters, help to control the range of polymer particle sizes obtained during polymer particle layer formation. In some embodiments, the evacuation phase comprises isolating the vacuum chamber from flow into the chamber and evacuating the chamber to a target pressure. In some embodiments, the target pressure can be between about 0.01 mTorr to about 400 mTorr; in further embodiments, between about 0.01 mTorr to about 200 mTorr; and in further embodiments, between about 0.1 mTorr to about 100 mTorr. A person of ordinary skill in the art will recognize additional ranges within the explicitly claimed rages are contemplated and within the present disclosure.

In some embodiments, it can be desirable to maintain the plasma through each pulse cycle and between cycles. It can be more efficient to maintain the plasma rather than letting it extinguish and re-igniting the precursor composition during a subsequent pulse cyle to re-establish the plasma. However, in some embodiments, desirable hydrophobic coatings can still be deposited if the plasmas is extinguished during a pulse cycle and/or between pulse cycles.

### EXAMPLES

### Example 1

### Structure and Performance of Hydrophobic Layers Deposited on Semiconductor Substrates: Pulsed Precursors and Pulsed Plasmas

This example demonstrates the structure and hydrophobic performance of a polymer coating on a silicon substrates, the polymer layer consisting of a hydrophobic layer comprising a particulate polymer layer. The polymer layer was formed using the adapted PECVD processing approaches described herein and incorporating pulsed precursors and pulsed plasmas.

To demonstrate structure and hydrophobicity, two samples (samples 1 and 2) were formed. Each sample comprised a silicon chip substrate. Each silicon chip was first cleaned using a PECVD cleaning process. The silicon chips were placed in the vacuum chamber of a PECVD apparatus and the chamber was evacuated to via a mechanical pump to a pressure of about 0.1 mTorr. The chips were kept in the chamber for about 5 minutes at that pressure to allowing for outgassing of the substrate. After about five minutes, the vacuum chamber was backfilled with 99.9% pure oxygen until a pressure of about 50 mTorr was reached. Once the pressure stabilized, a plasma was generated with an average power density of 7.5 W/L using a RF frequency generator to generate a continuous wave RF field at a frequency of 13.56 MHz. The plasma was kept energized for about 30 seconds, after which time the RF generator was turned off and the vacuum chamber was subsequently evacuated to about 0.1 mTorr. Once the pressure of 0.1 mTorr was achieved, the hydrophobic layer was deposited using a pulsed RF field and by pulsing vaporized 1H,2H,2H-tridecafluorooctyl methacrylate (“TDFOM”) (sample 1) or 1H,1H,2H,2H-perfluorodecyl acrylate (“PFDA”) (sample 2) into the chamber. The RF field had a frequency of 13.56 MHz and was pulsed at rate of 100 kHz using a duty cycle of 2%. The RF field generated a plasma having an average power density of 0.15 W/L. Each PDFA pulse cycle comprised a pressurization phase having a target pressure of 50 mTorr, a soak phase having a duration of 15 seconds (sample 2) or 1 minute (sample 1), and an evacuation phase having a target pressure of 20 mTorr. The hydrophobic layer was deposited over 20 cycles. For sample 1, the deposited coating had an average thickness of about 250 nm+/−7 nm as determined by ellipsometry.

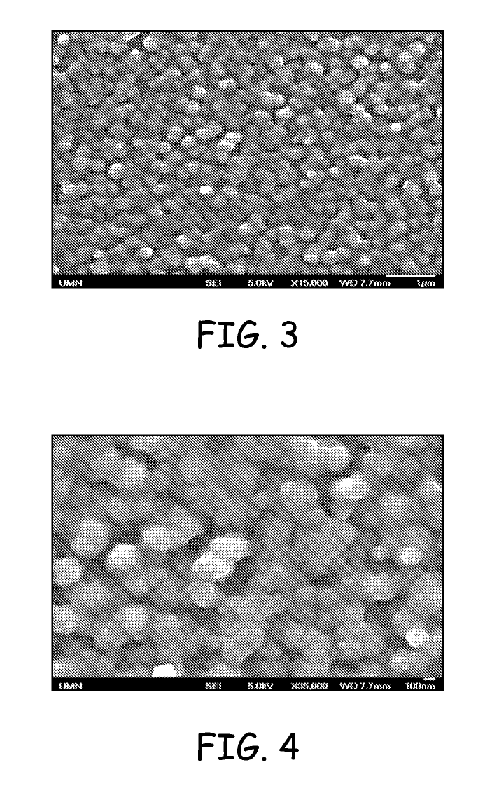

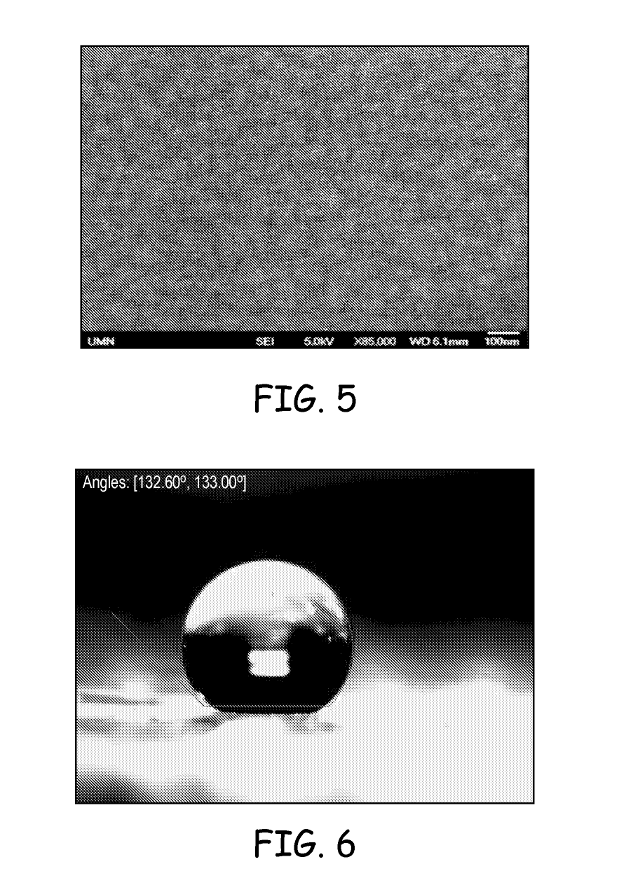

FIGS. 3 and 4 are SEM images of the coated surface of sample 1. FIG. 5 is an SEM image of the coated surface of sample 2. Referring to the figures, the coating comprises a fused particulate polymer layer comprising fused polymer particles having a range of primary particle diameters from about 150 nm to about 250 nm FIG. 4 is an SEM image of the coated surface of sample 2 demonstrating the hydrophobic layer comprised a non-regular pattern of fused polymer particles having a range of primary particle diameters from about 5 nm to about 20 nm. Comparison of FIGS. 3 and 4 with FIG. 5 demonstrates the ability to control the size of the nanoparticles using a different soak time.

To measure the hydrophobicity of sample 2, goiniometric analysis of the sample was performed using a VCA Optima S goniometer from AST Products, Inc. (Billerica, Mass.). Goiniometric analysis measures the contact angle of a water droplet on the surface of the substrate as described in detail above. A photographic image of sample 2 during goiniometric analysis as is shown in FIG. 6. The contact angle was measured to be about 132.5°, indicating the coating had an excellent level of hydrophobicity.

### Example 2

### Performance of Hydrophobic Layers Deposited on Mobile Computing Devices: Pulsed Precursors and Pulsed Plasmas

This example demonstrates the hydrophobic performance of a polymer coating on mobile phone substrates, the polymer layer consisting of a hydrophobic layer comprising a particulate polymer layer. The polymer layer was formed using the adapted PECVD processing approaches described herein and incorporating pulsed precursors and pulsed plasmas.

To demonstrate hydrophobicity, two additional samples (samples 3 and 4) were formed. Each substrate comprised an Apple iPhone® 4. The substrates were cleaned as described above in Example 1. After cleaning the vacuum chamber was subsequently evacuated to about 0.1 mTorr. Once the pressure of 0.1 mTorr was achieved, the hydrophobic layer was deposited using a pulsed RF field and by pulsing vaporized TDFOM (sample 3) or PDFA (sample 4) into the chamber. The RF field had a frequency of 13.56 MHz has was pulsed at rate of 100 kHz using a duty cycle of 2%. The RF field generated a plasma having an average power density of 0.15 W/L. Each PDFA pulse cycle comprised a pressurization phase having a target pressure of 50 mTorr, a soak phase having a duration of 15 seconds, and an evacuation phase having a target pressure of 20 mTorr. The hydrophobic layer was deposited over 20 cycles.

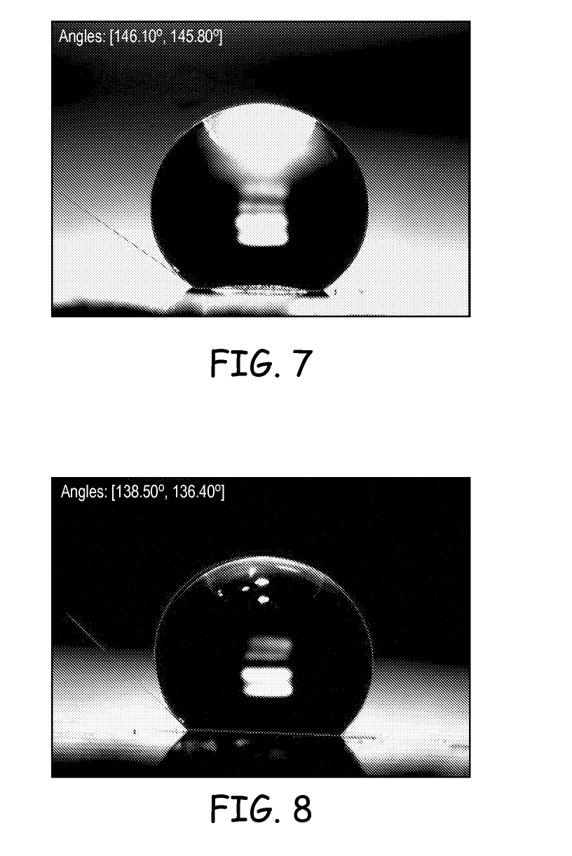

The hydrophobicity of the deposited layers was measured using goiniometric analysis as well as by performing industry standard water resistance test. With respect goiniometric analysis, FIGS. 7 and 8 are photographic images taken during analysis and demonstrate the contact angle of the water droplet on the coating of samples 3 and 4 was about 146° about 137°, respectively. The contact angle measurements demonstrate the coating on both substrates had excellent degrees of hydrophobicity, although the coating formed from TDFOM (sample 3) had improved hydrophobicity relative to the coating formed from PFDA (sample 4).

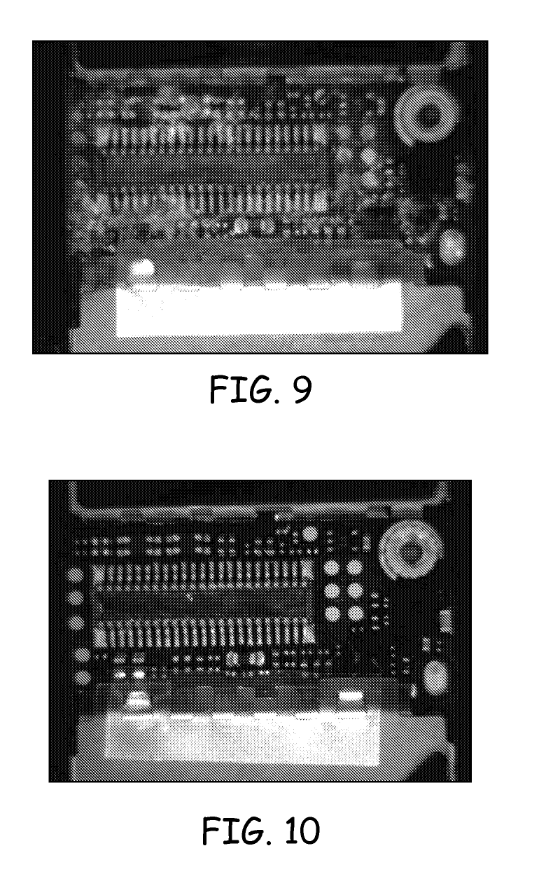

With respect to the industry standard tests, samples 3 and 4 powered on and submerged in 12 inches of tap water for 30 mins. Additionally, a control phone, an iPhone® 4, as purchased, was similarly powered on and submerged in tap water for 30 mins. After approximately 5 minutes, the control phone shut down in self-protective mode, and was extracted from the water. After 30 minutes, samples 3 and 4 were stilled powered-on and working. Samples 3 and 4 were left in the water for an additional 35 minutes with no discernible degradation of operation. Samples 3 and 4 were then extracted from the water and both phones were left in ambient atmosphere for 24 hours. After 24 hours, the phones of samples 3 and 4 and the control phone were disassembled and inspected for corrosion and photographic images were taken. FIGS. 9 and 10 are photographic images of an interior portion of the control phone and the phone of sample 3, respectively. The figures demonstrate that while the phone of sample 3 had no visible signs corrosion, the control phone had multiple points of large areas of corrosion. FIG. 10 is also representative of the interior of the phone of sample 4.

### Example 3

### Performance of Hydrophobic Layers Deposited on Non-Woven and Woven Materials: Pulsed Precursors and Pulsed Plasmas

This Example demonstrates the hydrophobic performance of a polymer coating on woven and non-woven material substrates, the polymer layer consisting of a hydrophobic layer comprising a particulate polymer layer. The polymer layers were formed using the adapted PECVD processing approaches described herein and incorporating pulsed precursors and pulsed plasmas.

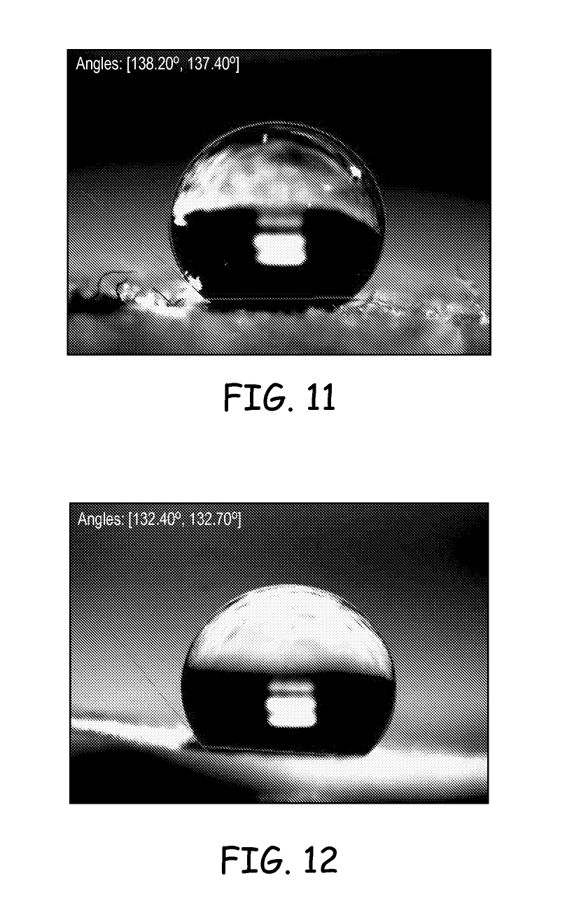

To demonstrate hydrophobicity, 3 additionally samples (samples 5-7) were formed. The substrate of samples 5 and 6 comprised a facial tissue (non-woven material) and the substrate of sample 7 comprised a 100% cotton t-shirt (woven material). A polymer coating consisting of a hydrophobic layer was deposited on the each or of the substrate as described in Example 1. For samples 5 and 7, a PFDA was used to form the hydrophobic layer and, for sample 6, TDFOM was used to form the hydrophobic layer. Goniometric analysis was performed on each sample and photographic images taken during analysis of samples 5-7 are displayed in FIGS. 11-13, respectively. The figures demonstrate that the coating of all the samples were extremely hydrophobic. Moreover, the figures demonstrate that the coatings of sample 5 was more hydrophobic than sample 6 (contact angles of 138° and 132.5°, respectively) while the coating of sample 7 was the most hydrophobic (contact angle of 143.5°), relative to the other samples tested in this Example.

### Example 4

### Performance of Dual Layer Polymer Coatings

This Example demonstrates the electrical insulation performance and hydrophobic performance of a polymer coating on a circuit board substrate, the polymer coating comprising a hydrophobic layer and an electrically insulating layer formed using the adapted PECVD processing approaches described herein.

To demonstrate electrical insulation performance, an additionally sample (sample 8) was formed. The substrate of the sample comprised a printed circuit board (Datak 12-612b) obtained from a retail supplier. The printed circuit board comprised 2 copper traces, approximately 2 mm across by 30 mm long and 2 mm apart on one side. Prior to deposition, the substrate was initially cleaned by wiping it down with isopropyl alcohol (“IPA”) and was subsequently subjected to a plasma cleaning process. To plasma clean the substrate, it was placed in a vacuum chamber of a PECVD apparatus and the vacuum chamber was evacuated to about 0.5 mTorr. The chamber was then heated with external rope heaters to 45° C. The temperature was held constant at 45° C. for the subsequent coating deposition process. When the vacuum chamber had stabilized in both temperature and pressure, argon gas was bled into the chamber until the pressure stabilized at 100 mTorr+/−2 mTorr. Once the chamber had against stabilized in temperature and pressure, the substrate was etched for 1 minute with a plasma having an average power of 300 W formed from the argon has using continuous wave RF field at 13.56 MHz. After the 1 minute etch period, the chamber was again evacuated to 0.5 mTorr.

To form the electrically insulating layer, the vacuum chamber was backfilled with vaporized PFDA to a pressure of 400 mTorr, and held constant at this pressure during the subsequent deposition. Once a pressure of 400 mTorr was achieved, a plasma having an average power of 300 W was formed from the vaporized PFDA using an RF field at a frequency of 13.56 MHz. The plasma was energized for 5 minutes during which time the electrically isolated layer was deposited on the substrate. After the 5 minutes, the vacuum chamber was evacuated to 0.5 mTorr. Once the pressure of 0.5 mTorr was achieved, the hydrophobic layer was deposited using a pulsed RF field and by pulsing vaporized PDFA into the chamber. The RF field had a frequency of 13.56 MHz has was pulsed at rate of 100 kHz using a duty cycle of 2%. The RF field generated a plasma having an average power density of 5 W/L. Each PDFA pulse cycle comprised a pressurization phase having a target pressure of 50 mTorr, a soak phase having a duration of 15 seconds and an evacuation phase having a target pressure of 40 mTorr. The hydrophobic layer was deposited over 20 cycles. After deposition of the hydrophobic layer, the plasma was extinguished, the vacuum chamber was vented and the sample was removed from the vacuum chamber. Ellipsometry measurements taken of sample 8 demonstrated dual layer coating had a combined thickness between about 300 nm and 500 nm.

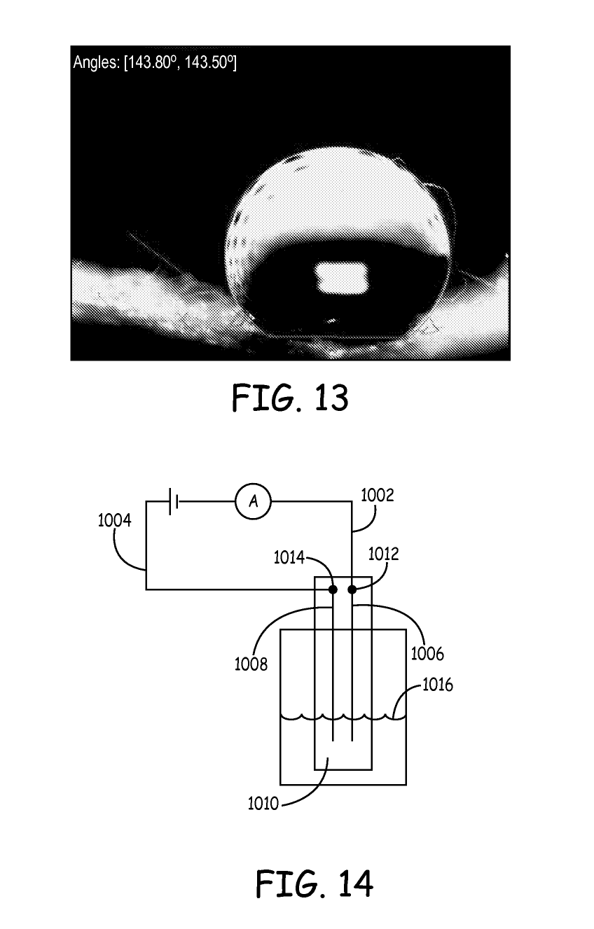

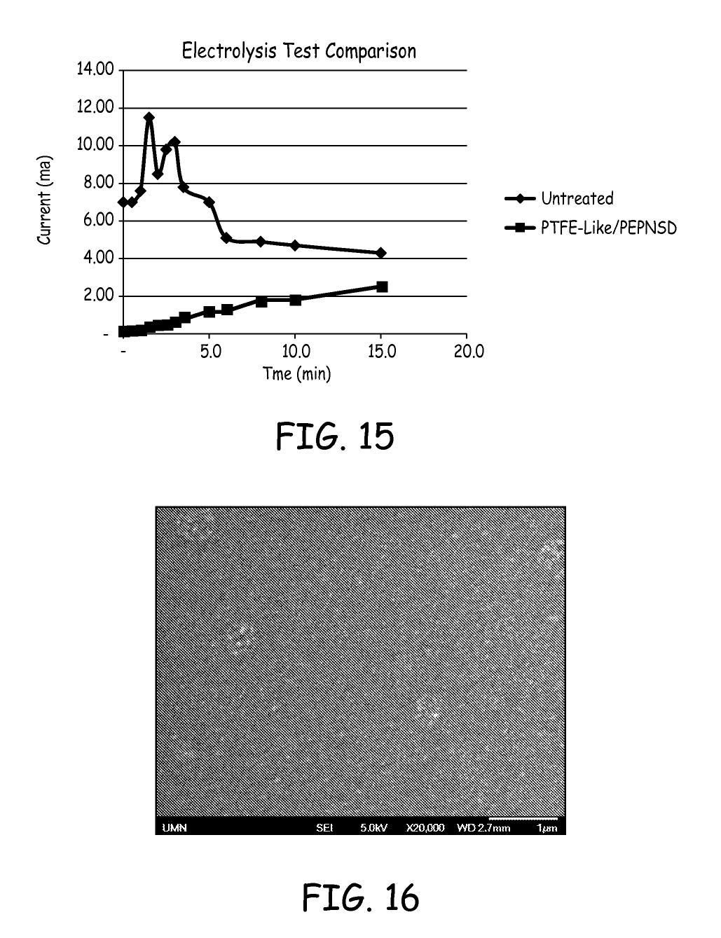

To test the electrical insulation performance of sample 8, after deposition of the polymer coating, an 18 gauge wire was soldered to each of the ends of the two traces and the ends were subsequently connected to a Tenma Laboratory DC Power Supply model 72-2005 (3 A, 20V max) power supply, one wire to the positive side and the other wire to the negative side. Additionally, a control Datak 12-612b circuit board, as purchased, was electrically connected to the power supply as described above with respect to sample 8. The sample 8 and the control board were then placed in 20 mm of tap water such that the wire-trace attachment points were not submerged. A schematic depiction of the electrolysis test setup is displayed in FIG. 14. Referring to the figures, wires 1002, 1004 are respectively attached to traces 1006, 1008 of the substrate 1010 at attachment points 1012, 1014 which are above water level 1016. Subsequently, the power supply was turned on, set at a constant voltage of 4.5 V, and the increase in current passed between the 2 traces of each board via the water was measured over time at 30 second intervals. FIG. 15 is a graph displaying plots of the current versus time for the sample 8 and the control sample. Referring to the figure, after 15 minutes, the control circuit board never passed less than 4 mA current and went as high as 11.5 mA while over the same time period, sample 8 never passed more than 2.4 mA, demonstrating good electrically insulating performance of the dual layer polymer coating deposited on the substrate of sample 8.

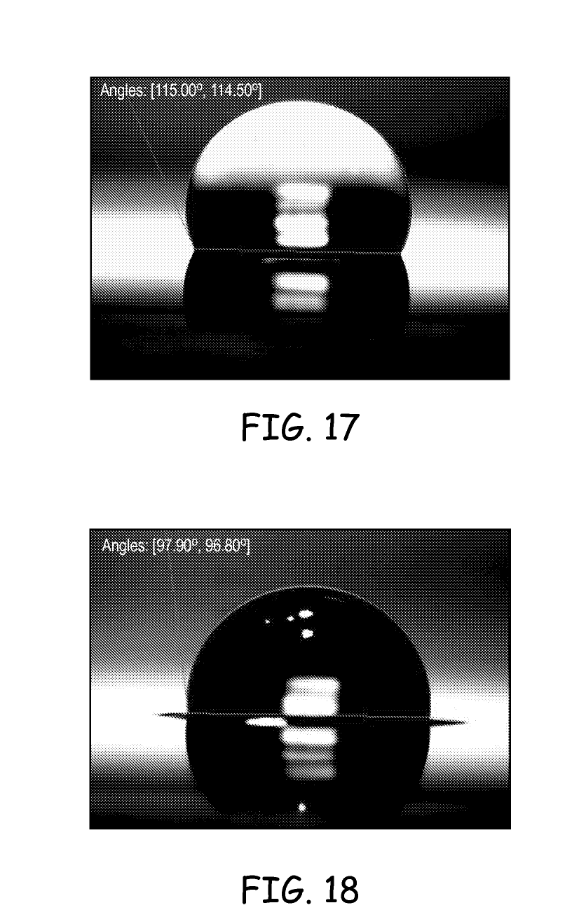

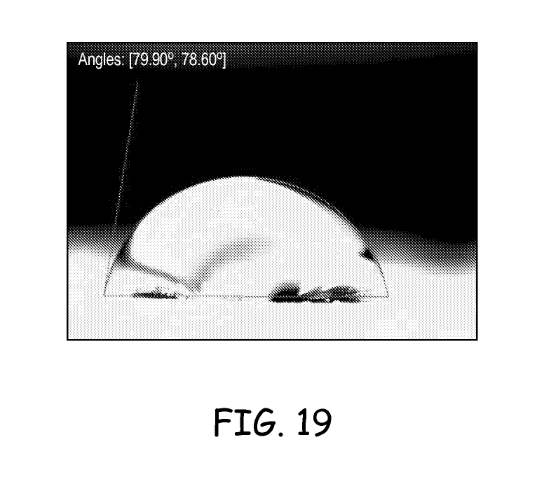

To test the hydrophobic performance contribution of the hydrophobic layer to the dual layer polymer coating, a further sample (sample 9) was formed as described above with respect to sample 9, however, only an electrically insulating layer was deposited on the circuit board substrate. FIG. 16 is a SEM image of the coated surface of sample 9. Goiniometric analysis of samples 8, 9 and the control sample were performed and photographic images taken during the analysis are displayed in FIGS. 17-19, respectively. Referring to FIG. 19, the contact angle of the control sample was 79 degrees, indicating the surface of the sample is not generally considered to be hydrophobic. FIG. 18 reveals the contact angle of sample 9 was 97, indicating the electrically insulating layer can be mildly hydrophobic. As seen from FIG. 17, the contact angle of sample 8 was 115 degrees, indicated significantly improved hydrophobicity of the dual layer polymer coating relative to the insulating layer alone.

### Example 5

### Prophetic Example of Performance of Hydrophobic Layers Deposited on Semiconductor Substrates: Pulsed Precursors and Continuous Waver Plasmas

This prophetic example provides expected results regarding the structure and hydrophobic performance of a polymer coating on a silicon substrates, where the polymer layer consists of a hydrophobic layer comprising a particulate polymer layer. The polymer layer are contemplated as being formed using the adapted PECVD processing approaches described herein and incorporating pulsed precursors and continuous wave (“CW”) plasmas.

Two samples are contemplated as being formed using the following process: A substrate comprising a silicon wafer, atomically flat, is placed in a vacuum chamber between two electrodes. The chamber is evacuated via mechanical pump to the level of 1×10⁻⁴ Torr where it is allowed to outgas for five minutes. After the outgassing is completed, the chamber is backfilled with 99.9% pure oxygen to a constant level of 50 mTorr. Once the pressure in the chamber is stabilized, a plasma is ignited using a radio frequency (RF) generator with a frequency of 13.56 mHz at a constant power of 500 watts. This plasma is kept energized for 30 seconds, at which time, the RF generator is turned off and the vacuum chamber is again evacuated to 1 E⁻⁴ Torr. Once the base pressure is achieved, the chamber is pulsed with a TDFOM (sample 10) or PFDA (sample 11) precursor vaporized at 150° C. through a Swagelok 6LVV-ALD-3TG-333P-CV valve with a cycle time of 0.1 s per pulse. The RF power supply is energized and a plasma is ignited during the first pulse and is not allowed to extinguish during the entire deposition process. Once the TDFOM (sample 10) or PFDA (sample 11) pulse is started, the vacuum valve is closed for a period of 30 seconds. After this 30 seconds, the vacuum valve is reopened and allowed to pump for 10 seconds. After this 10 seconds is up, the monomer is pulsed in again for 0.1 s and the process is repeated 200 times producing the resultant surface modification.

Using the contemplated formation process describe above, it is expected that, for sample 10, the resultant surface modification will show a water contact angle of approximately 146° as measured by an AST Products, Inc. VCA Optima S goniometer. Additionally, scanning electron micrographs are expected to show the structure of the polymer particles of 150 to 250 nm in diameter in a non-regular pattern on the surface of the silicon wafer. The thickness of this surface modification is expected to measure, via ellipsometery, 250 nm+/−7 nm.

For sample 11, it is expected that the resultant surface modification will show, via goniometer measurement, a water contact angle of 133° as measured by an AST Products, Inc. VCA Optima S goniometer. Additionally, from the scanning electron micrographs, it is expected that the structure will show polymer particles of a much smaller diameter, 5 nm to 20 nm, in a non-regular pattern on the surface of the silicon wafer. Thickness of this surface modification is expected to measure, via ellipsometery, 275 nm thick+/−10 nm. Sample 11, contrasted with sample 10, shows the ability to control the size of the polymer particles.

### Example 6

### Prophetic Example of Performance of Hydrophobic Layers Deposited on Mobile Computing Devices: Pulsed Precursors and CW Plasmas

This prophetic example provides expected results regarding the structure and hydrophobic performance of a polymer coating on a mobile phone substrate, where the polymer layer consists of a hydrophobic layer comprising a particulate polymer layer. The polymer layer are contemplated as being formed using the adapted PECVD processing approaches described herein and incorporating pulsed precursors and CW plasmas.

Two samples are contemplated as being formed using the following process: An iPhone® 4 is placed in a vacuum chamber between two electrodes. The chamber is evacuated via mechanical pump to the level of 1×10⁻⁴ Torr where it is allowed to outgas for five minutes. After the outgassing is completed, the chamber is backfilled with 99.9% pure oxygen to a constant level of 50 mT. Once the pressure in the chamber has stabilized, a plasma is ignited using a radio frequency (RF) generator with a frequency of 13.56 mHz at a constant power of 500 watts. This plasma is kept energized for 30 seconds, at which time, the RF generator is turned off and the vacuum chamber is again evacuated to 1 E-4 Torr. Once the base pressure is achieved, the chamber is pulsed with TDFOM (sample 12) or PFDA (sample 13) precursor vaporized at 150° C. through a Swagelok 6LVV-ALD-3TG-333P-CV valve with a cycle time of 0.1 s per pulse. The RF power supply is energized and a plasma is ignited during the first pulse and is not allowed to extinguish during the entire deposition process. Once the TDFOM (sample 12) or PFDA (sample 13) pulse is started, the vacuum valve is closed for a period of 30 seconds. After this 30 seconds, the vacuum valve is reopened and allowed to pump for 10 seconds. After this 10 seconds is up, the monomer is pulsed in again for 0.1 s and the process is 10 repeated 200 times producing the resultant surface modification. Using the contemplated formation process describe above, it is expected that, for samples 12 and 13, the resultant surface modification will respectively show a water contact angle of 138° and 137° as measured by an AST Products, Inc. VCA Optima S goniometer.

Additionally, when subjected to several industry standard water resistant tests, it is expected that samples 12 and 13 will have good performance. In the most rigorous of tests, the two samples and an untreated iPhone® 4, will be powered on and submerged in 12 inches of tap water for 30 minutes. It is expected that after approximately 5 minutes, the untreated iPhone® 4 will shut down in self-protective mode, and be extracted from the water. After 30 minutes, it is expected that samples 12 and 13 will still be on and working. It is expected that samples 12 and 13 can be left in the water for an additional 25 minutes with no degradation of operation. It is also expected that if samples 12 and 13 are extracted from the water, are left in ambient atmosphere for 24 hours, and be disassembled and inspected for corrosion after 24 hours, the substrates will show essentially no signs of corrosion, while, the untreated iPhone® 4 will have multiple points of large areas of corrosion. The resistance to corrosion is not an effect that would be expected based on the use of conventional processes.

### Example 7

### Prophetic Example of Performance of Hydrophobic Layers Deposited on Non-Woven and Woven Materials: Pulsed Precursors and CW Plasmas

This prophetic Example provides expected results regarding the hydrophobic performance of a polymer coating on woven and non-woven material substrates, where the polymer layer consists of a hydrophobic layer comprising a particulate polymer layer. The polymer layers are contemplated as being formed using the adapted PECVD processing approaches described herein and incorporating pulsed precursors and CW plasmas.

Three samples are contemplated being formed using the following process: a swatch of non-woven material (tissue) (samples 14 and 15) are a swatch of woven material (typically a 100% cotton t-shirt) (sample 16) is placed in a vacuum chamber between two electrodes. The chamber is evacuated via mechanical pump to the level of 1×10⁻⁴Torr where it is allowed to outgas for five minutes. After the outgassing is completed, the chamber is backfilled with 99.9% pure oxygen to a constant level of 50 mTorr. Once the pressure in the chamber has stabilized, a plasma is ignited using a radio frequency (RF) generator with a frequency of 13.56 mHz at a constant power of 500 watts. This plasma is kept energized for 30 seconds, at which time, the RF generator is turned off and the vacuum chamber is again evacuated to 1×10⁻⁴ Torr. PFDA (samples 14 and 16) or TDFOM (sample 15) monomer is vaporized at 150° C. through a Swagelok 6LVV-ALD-3TG-333P-CV valve with a cycle time of 0.1 s per pulse. The RF power supply is energized and a plasma is ignited during the first pulse and is not allowed to extinguish during the entire deposition process. Once the PFDA pulse is started, the vacuum valve is closed for a period of 30 seconds. After this 30 seconds, the vacuum valve is reopened and allowed to pump for 10 seconds. After this 10 seconds is up, the monomer is pulsed in again for 0.1 s and the process is repeated 200 times producing the resultant surface modification.

Using an AST Products, Inc. VCA Optima S goniometer, it is expected that the surface contact angle will be measured using water and the surface modification will show a water contact angle of 138°, 132.5° and 143.5° for samples 14-16, respectively.

### Further Inventive Concepts

1. A method for forming a protective coating on a substrate, the method comprising:

depositing a collection of polymer particles having an average primary particle diameter of from about 20 nm to about 10 microns on the substrate to form a fused particle layer, wherein the depositing comprises pulsing a first precursor comprising a monomer into a pulsed or continuous RF plasma to form the particles by a chemical reaction comprising the monomer.

2. The method of 1 wherein the first precursor comprises an epoxide monomer represented by the formula:

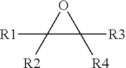

R₁, R₂ and R₃ are hydrogens and R₄ is represented by the formula —CH₂(CF₂)ₙCF₃, where n is 1 to 20; or

wherein the first precursor composition comprises a vinyl monomer represented by the formula R₅R₆C═CR₇R₈, wherein R₆, R₇, and R₈ can be independently be a hydrogen, a halogen, of a fluorinated or perfluoronated linear or branched, saturated or unsaturated, hydrocarbon chain having 1 to 20 carbon atoms; and wherein R₁ is represented by the formula —COOR₉ and wherein R₉ can be hydrogen or a hydrocarbyl group

3 The method of 2 wherein R₁, R₂, and R₃, are each H and R₄ is the group —CH₂(CF₂)ₘCF₃, where in is between 1 and 20.
4. The method of any of 1 to 3 wherein the first precurosr comprises 3-(perfluorooctyl)propyl epoxide and 3-(perfluorohexyl)propyl epoxide.
5. The method of any of 1 to 4 wherein the first precurosr comprises 1H,1H,2H,2H-tridecylfluorooctyl methacrylate or 1H,1H,2H,2H-perfluorodecyl acrylate.
6. The method of any 1 to 5 wherein the plasma has an average volumetric energy density from about 0.001 W/L to about 10 W/L.
7. The method of any of 1 to 6 wherein the plasma is a pulsed plasma generated with an RF filed is pulsed at a rate of about 5 kHz to about 250 kHz at a duty cycle of about 0.5% to about 5% or a continuous wave plasma generated with an RF field.
8. The method of any of 1 to 7 wherein the first precursor is pulsed into the chamber during a plurality of pulse cycles and wherein a pulse cycle comprises a pressurization phase, a soak phase, and an evacuation phase;

wherein the pressurization phase comprises introducing a monomer precursor into the vacuum chamber until a target pressurization pressure is reached;

wherein the soak phase comprises restricting flow of the monomer into the reaction chamber for a target duration; and

wherein the evacuation phase comprises evacuating the vacuum chamber to a target evacuation pressure.

7. The method of 6 wherein the first precursor is pulsed into the chamber during from about 10 to about 10,000 pulse cycles, wherein the target pressurization pressure is from about 0.01 mTorr to about 500 mTorr, wherein the target duration is from about 0.1 seconds to about 10 minutes and wherein the evacuation pressure is from about 0.01 mTorr to about 400 mTorr.
8. The method of 1 to 7 wherein the fused particle layer is deposited directly or indirectly on at least a portion of an article having an electrically insulating layer formed with a process that comprises exposing, in a vacuum chamber, the portion of the article to a continuous wave plasma formed from a second precursor composition comprising an epoxide monomer represented by the formula:

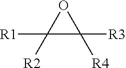

wherein R₁, R₂ and R₃ are hydrogens and R₄ is represented by the formula —CH₂(CF₂)ₙCF₃, where n is 1 to 20; or

from a second precursor composition comprising an vinyl monomer represented by the formula R₅R₆C═CR₇R₈, wherein R₆, R₇, and R₈ can be independently be a hydrogen, a halogen, of a fluorinated or perfluoronated linear or branched, saturated or unsaturated, hydrocarbon chain having 1 to 20 carbon atoms; and wherein R₁ is represented by the formula —COOR₉ and wherein R₉ can be hydrogen, or a hydrocarbyl group.

9. The method of 8 wherein the continuous wave plasma formed from the second precursor compositions has an average volumetric energy density from about 0.001 W/L to about 10 W/L.
10. The method of any of 8 to 9 wherein the electrically insulating layer is essentially free of pin-holes that would allow water to pass therethrough when submerged in 1 foot of water for 1 hour.
11. The method of any of 1 to 10 wherein the fused particle layer is a hydrophobic layer having a water contact angle of between about 115° to about 150°.
12. The method of 1 to 11 wherein the fused particle layer has an average thickness of about 1 nm to about 500 nm.
13. The method of any of 8 to 12 wherein the wherein the electrically insulating layer has an average thickness of about 200 nm to about 300 nm.
14. The method of any of 1 to 13 wherein the substrate comprises an electronic device or a portion thereof or a fabric or a portion thereof.

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

1-40. (canceled)

41. A method for forming a protective coating on a substrate, the method comprising:
depositing a collection of polymer particles having an average primary particle diameter of from about 20 nm to about 10 microns on the substrate to form a fused particle layer.

42. The method of claim 41 wherein the polymer particles have an average primary particle diameter of from about 20 nm to about 200 nm.

43. The method of claim 41 comprising pulsing a first precursor comprising a monomer into a plasma enhanced chemical vapor deposition chamber to form the particles by a chemical reaction comprising the monomer.

44. The method of claim 41 wherein the plasma is pulsed.

45. The method of claim 41 wherein the particles are spheroidal.

46. The method of claim 41 wherein the depositing comprises exposing, in a vacuum chamber, the substrate to a pulsed plasma formed from a first precursor composition comprising a first monomer represented by the formula R₁R₂C═CR₃R₄;
wherein R₂, R₃, and R₄ can be independently be a hydrogen, a halogen, of a fluorinated or perfluoronated linear or branched, saturated or unsaturated, hydrocarbon chain having 1 to 20 carbon atoms; and
wherein R₁ is represented by the formula —COOR₅ and wherein R₅ can be hydrogen, or a hydrocarbyl group; and
wherein the plasma is generated using a pulsed RF field.

47. The method of claim 41 wherein the first monomer comprises 1H,1H,2H,2H-tridecylfluorooctyl methacrylate or 1H,1H,2H,2H-perfluorodecyl acrylate.

48. The method of claim 46 wherein the first precursor composition further comprises a second monomer represented by the formula R₁R₂C═CR₃R₄;
wherein R₂, R₃, and R₄ can be independently be a hydrogen, a halogen, of a fluorinated or perfluoronated linear or branched, saturated or unsaturated, hydrocarbon chain having 1 to 20 carbon atoms; and
wherein R₁ is represented by the formula —COOR₅ and wherein R₅ can be hydrogen, or a hydrocarbyl group; and
wherein the first monomer is distinct form the second monomer.

49. The method of claim 48 wherein the first precursor composition comprises argon, hydrogen, nitrogen, oxygen, ozone or a mixture thereof.

50. The method of claim 48 wherein the RF filed is pulsed at a rate of about 5 kHz to about 250 kHz at a duty cycle of about 0.5% to about 5%.

51. The method of claim 46 wherein the first monomer is pulsed into the chamber during a plurality of pulse cycles.

52. The method of claim 51 wherein a pulse cycle comprises a pressurization phase, a soak phase, and an evacuation phase;
wherein the pressurization phase comprises introducing a monomer precursor into the vacuum chamber until a target pressurization pressure is reached;
wherein the soak phase comprises maintaining the pulsed plasma at constant volume for a target duration; and
wherein the evacuation phase comprises evacuating the vacuum chamber to a target evacuation pressure.

53. The method of claim 52 wherein the target pressurization pressure is from about 0.01 mTorr to about 500 mTorr.

54. The method of claim 52 wherein the target pressurization duration phase is from about 0.1 seconds to about 120 seconds.

55. The method of claim 52 wherein the evacuation pressure is from about 0.01 mTorr to about 400 mTorr.

56. The method of claim 41 wherein the substrate comprises a polymer layer on an article, wherein the fused particle layer is deposited onto the polymer layer.

57. The method of claim 56 wherein the polymer layer is deposited directly or indirectly on at least a portion of an article with a process that comprises exposing, in a vacuum chamber, the portion of the article to a continuous wave plasma formed from a second precursor composition comprising a second monomer represented by the formula R₁R₂C═CR₃R₄;
wherein R₂, R₃, and R₄ can be independently be a hydrogen, a halogen, of a fluorinated or perfluoronated linear or branched, saturated or unsaturated, hydrocarbon chain having 1 to 20 carbon atoms; and
wherein R₁ is represented by the formula —COOR₅ and wherein R₅ can be hydrogen, or a hydrocarbyl group; and
wherein the continuous wave plasma is generated using continuous RF field.

58. The method of claim 41 wherein the article comprises an electronic device and/or a component of an electronic device, with the substrate being applied directly or indirectly to one or more surfaces of said article; or wherein the article comprises a semiconductor sheet comprising an integrated circuit, with the substrate being applied directly or indirectly to one or more surfaces of said article; or wherein the article comprises a computing device, with the substrate being applied directly or indirectly to one or more surfaces of said article; or wherein the article comprises a fabric with the substrate being applied directly or indirectly to one or more surfaces of said article.

59. A coating on a substrate, the coating comprising a first polymer layer disposed directly or indirectly on the substrate and a second polymer layer disposed in contact with the first polymer layer, wherein the second polymer layer comprises fused polymer particles having an average primary particle size of from about 200 nm to about 100 microns.

60. The coating of claim 59 wherein the first polymer layer is an electrically insulating layer and wherein the second polymer layer is a hydrophobic layer.

61. The coating of claim 60 wherein the first polymer layer has an average thickness of about 1 nm to about 500 nm and the second polymer layer has an average thickness of about 1 nm to about 500 nm.

62. The coating of claim 61 wherein the first polymer layer has an average thickness of about 100 nm to about 200 nm.

63. The coating of claim 62 wherein the second polymer layer has an average thickness of about 200 nm to about 300 nm.

64. The coating of claim 59 wherein the substrate is at least a portion of a semiconductor sheet comprising an integrated circuit, or at least a portion of a computing device, or wherein the substrate comprises a fabric.

65. A coating on a substrate, the coating comprising a polymer layer comprising fused polymer particles having an average primary particle size of from about 200 nm to about 100 microns disposed directly or indirectly on the substrate, wherein the contact angle between a water droplet on the surface of the polymer layer the polymer layer has a contact angle of between about 115° to about 150°.
